(19) United States
(12) Patent Application Publication
(10) Pub. No.: US 2012/0140541 A1
(43) Pub. Date: Jun. 7, 2012

(54) MEMORY BUILT-IN SELF TEST SCHEME FOR CONTENT ADDRESSABLE MEMORY ARRAY

(75) Inventors: Kyle S. Viau, Fremont, CA (US); James Vinh, San Jose, CA (US)

(73) Assignee: ADVANCED MICRO DEVICES, INC., Sunnyvale, CA (US)

(21) Appl. No.: 12/958,539

(22) Filed: Dec. 2, 2010

(51) Int. Cl. G11C 29/38; G06F 11/26; G11C 15/00

(52) U.S. Cl. 365/49.17; 716/136

(57) ABSTRACT

A method and apparatus for testing a content addressable memory (CAM) array includes writing known data to the CAM array and providing comparison data to the CAM array. A determination is made whether the CAM array is operating correctly responsive to a comparison of the known data and the comparison data.

### FIELD OF INVENTION

The present invention is directed to integrated circuits and in particular, to integrated circuits having memory built-in self test (MBIST) circuitry and related methods.

### BACKGROUND

Integrated circuits having memory arrays that are designed and manufactured with memory built-in self test (MBIST) circuitry are well-known. Integrated circuits employing MBIST generally include multiple different size arrays of memory elements that require testing. Typically during MBIST testing, a test vector is written into an array and then a read operation is performed with the results analyzed to confirm proper operation of the array under the test vector. Within a given component or section of an integrated circuit, each array of that component is conventionally tested in series to analyze the application of the respective test vector with the respective array.

Integrated circuits that include Content Addressable Memories (CAMs) are also well known. CAM circuitry compares input search data against data stored in CAM arrays and identifies whether or not the input data matches the data stored in one or more of the memory arrays.

In one type of application, CAMs are used in connection with processor schedulers that schedule the execution of processor instructions/operations. Schedulers are known that use wakeup logic to trace instruction dependence and wake up instructions when their source operands become available. Wakeup logic can be implemented by using CAMs that fully match all the source tags in an issue window with result tags stored in a random access memory (RAM).

Testing the RAM portion of the integrated circuit is relatively straightforward. Each RAM cell has a dedicated read port that allows the data read out of a RAM cell to be directly compared to the data that was written in. A test vector is written to a RAM cell and a read operation is performed using the dedicated read port of that cell. The data read out of the RAM cell is then compared to the test data written in. If the data matches, the RAM is operating properly.

Testing the CAM portion of the integrated circuit requires additional steps. Unlike RAM cells, CAM cells do not have dedicated read ports. Instead, the CAM cells have match outputs that indicate either a data match or a data mismatch. As a result, the contents of CAM cells cannot be simply read out during an MBIST process.

One way of testing the CAM cells would be to add read ports to each CAM cell and allow a direct read of the data stored in each cell. This is undesirable because the additional read ports would only be used in the MBIST operation, causing an inefficient use of circuit area and would slow down read and comparison operations.

### SUMMARY OF EMBODIMENTS

A method of testing a content addressable memory (CAM) array includes writing known data to the CAM array and providing comparison data to the CAM array. A determination is made whether the CAM array is operating correctly responsive to a comparison of the known data and the comparison data.

An apparatus for testing a CAM array includes a test engine and a CAM array. The test engine is configured to write known data to the CAM array and to provide comparison data to the CAM array. The CAM array is configured to perform a comparison between the known data and the comparison data. The test engine is further configured to determine whether the CAM array is operating correctly responsive to the comparison.

A computer-readable storage medium storing a hardware design code representing an integrated circuit device configured to test a CAM array includes a writing code segment, a providing code segment, and a determining code segment. The writing code segment is for writing known data to the CAM array. The providing code segment is for providing comparison data to the CAM array. The determining code segment is for determining whether the CAM array is operating correctly responsive to a comparison of the known data and the comparison data.

### BRIEF DESCRIPTION OF THE DRAWINGS

A more detailed understanding of the invention may be had from the following description, given by way of example, and to be understood in conjunction with the accompanying drawings, wherein:

FIG. 1 is a block diagram of memory built-in self test (MBIST) circuitry.

FIG. 2 is a block diagram of an integrated circuit having a processor core with MBIST master and slave circuitry.

FIG. 3 is a block diagram of an MBIST scheme for the Wake Up CAM array.

FIG. 4 is a flow chart of a method of testing the source CAM array.

FIG. 5 is a flow chart of a method of testing the destination RAM array.

### DETAILED DESCRIPTION OF EMBODIMENTS

A method of testing a content addressable memory (CAM) array includes writing known data to the CAM array and broadcasting comparison data to the CAM array. A comparison is performed between the known data and the comparison data to generate a match signal if the known data and the comparison data match or a mismatch signal if the known data and the comparison data do not match. The match signal or the mismatch signal is evaluated to determine whether the CAM array is operating correctly.

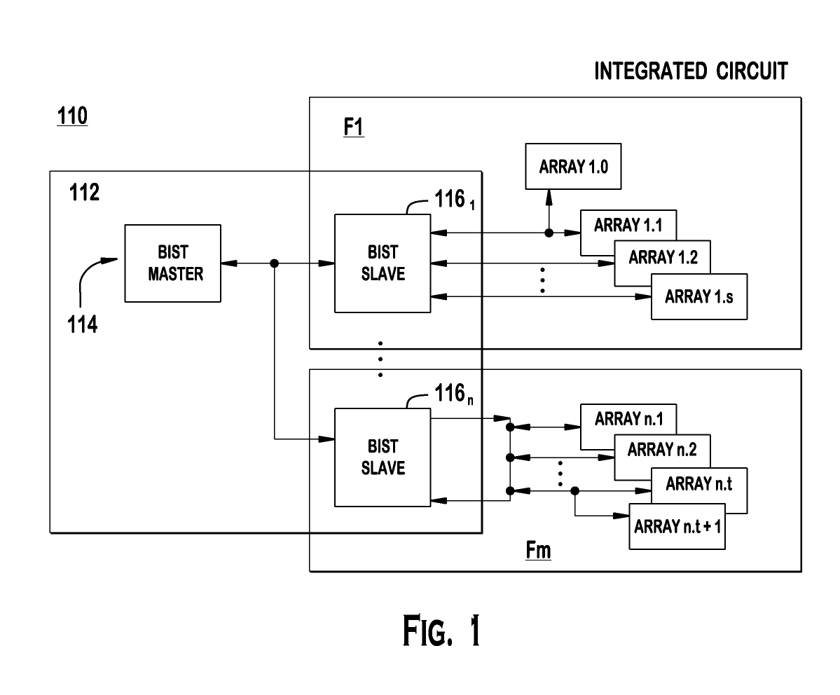

Referring to FIG. 1, an integrated circuit (IC) 110 is shown having various functional components F1, . . . , Fm that each include arrays of memory elements; Array 1.0 through Array 1.s of functional unit F1 and Array n.1 through Array n.t+1 of functional unit Fm. The IC 110 may have other functional components that do not include memory arrays or may have a single functional component that includes memory arrays. Generally, the IC 110 includes memory arrays of various sizes.

The IC 110 includes memory built-in self test (MBIST) circuitry 112 associated with multiple arrays of at least one functional unit. In the example embodiment illustrated in FIG. 1, the MBIST circuitry 112 includes MBIST master circuitry 114 that controls a plurality of MBIST slave circuits, BIST Slave 116₁ through BIST Slave 116ₙ, through a ring type bus interface.

Each MBIST slave circuit 116₁-116ₙ is associated with multiple arrays of one of the functional units. A MBIST slave circuit is associated with each functional unit that has memory arrays, but some functional units may be associated with multiple MBIST slave circuits such that each MBIST slave circuit is associated with different sets of arrays within the functional unit. The MBIST circuitry 112 is configured to conduct serial testing of the arrays within each functional unit that it is associated.

For a processor application, the MBIST slave circuits typically are each associated with from five to twenty arrays having memory elements that range in size from 64×32 bits to 256×512 bits. The number of arrays and array size may be outside such typical ranges. Where a functional unit has more than twenty arrays, the arrays are divided into sets that are each associated with a different MBIST slave circuit.

Either a star-type interface or a ring-type interface is used between each MBIST slave circuit and its associated arrays. FIG. 1 illustrates MBIST slave circuit 116₁ associated in a star-type configuration with Array 1.0 through Array 1.s of functional unit F1 and MBIST slave circuit 116ₙ associated in a ring-type configuration with Array n.1 through Array n.t+1 of functional unit Fm. In some cases, the interface between a MBIST slave circuit and its associated arrays may include logic connections shared by more than one array. For example, FIG. 1 illustrates shared logic in the interface between MBIST slave circuit 116₁ and arrays Array 1.0 and Array 1.1 and shared logic in the interface between MBIST slave circuit 116ₙ and arrays Array n.t and Array n.t+1.

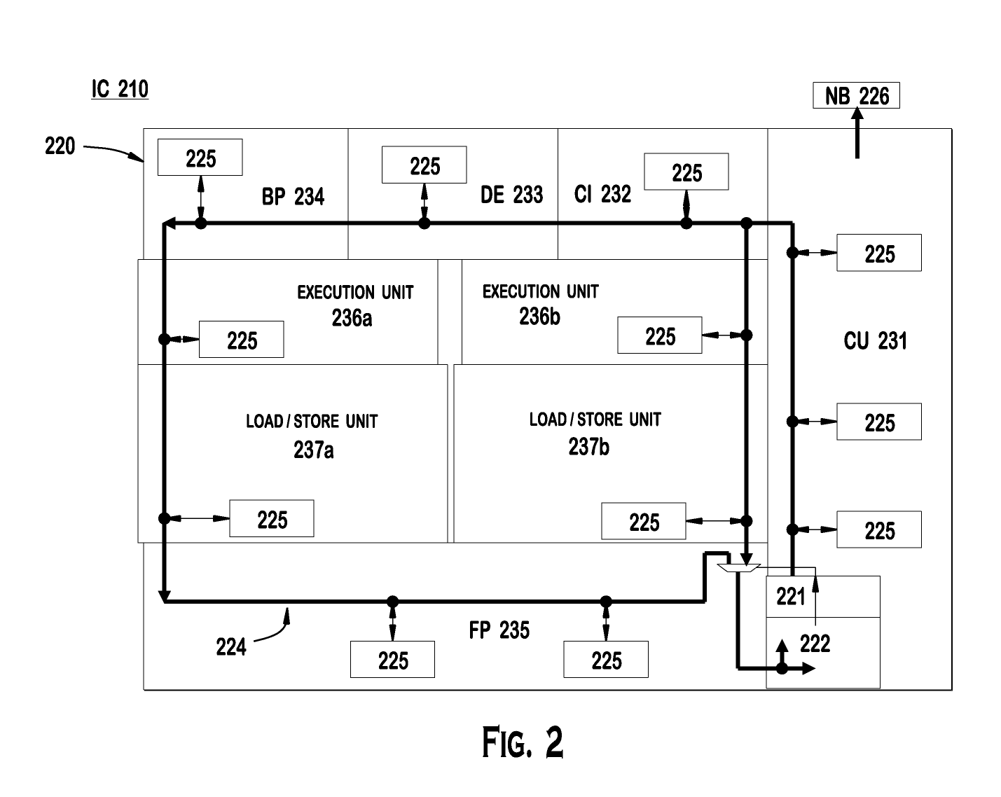

FIG. 2 shows an example embodiment of a multi-core processor IC 210 that includes processor core 220 interfacing with a North Bridge (NB) 226. The processor core 220 has multiple functional components with multiple memory arrays including a unified L2 Cache (CU) 231, an Instruction Cache (CI) 232, a Decoder unit (DE) 233, a Branch Prediction unit (BP) 234, a Floating Point unit (FP) 235, two Execution units 236a, 236b, and two Load/Store units 237a, 237b, for dual thread processing.

The processor core 220 includes debug circuitry 222 in communication with the various functional components via a bus 224. MBIST processing circuitry is provided that includes MBIST master circuitry 221 and MBIST slave circuits 225. The MBIST master circuitry 221 is configured to utilize the bus 224 to communicate with the MBIST slave circuits 225.

One MBIST slave circuit 225 is associated with the memory arrays in each of the Instruction Cache 232, Decoder 233, Branch Prediction unit 234, Floating Point unit 235, Execution units 236a, 236b and Load/Store units 237a, 237b. Two MBIST slave circuits 225 are associated with different sets of the memory arrays in the Floating Point unit 235. Three MBIST slave circuits 225 are associated with different sets of the memory arrays in unified L2 Cache 231. Each MBIST slave circuit 225 is associated with a plurality of the arrays within each respective functional unit for both serial testing and parallel initialization of the plurality of arrays.

The MBIST master circuitry 221 is configured to send a global enable signal to each MBIST slave circuit 225 that enables MBIST operation on each array the MBIST slave circuit is connected to. There is a unique enable signal for each array so that only one array is tested at a time. When the enable signal is issued by the MBIST master circuitry 221, normal operation of the target array is disabled. The enable signals for each array in the IC 210 are issued such that each array is sequentially tested for proper operation.

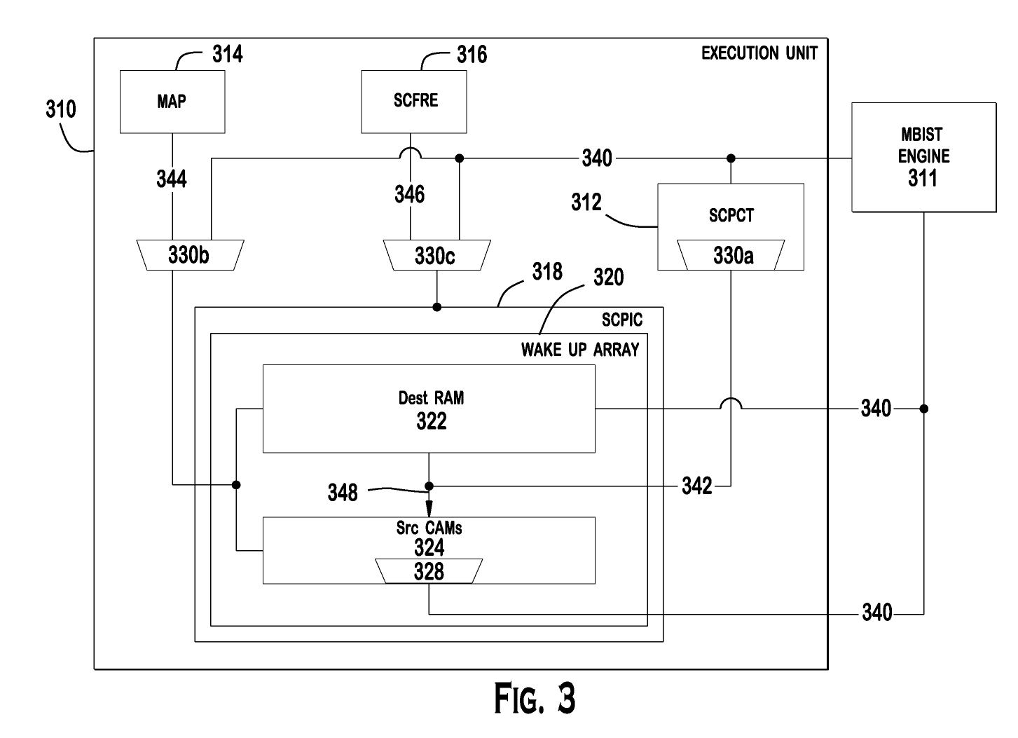

FIG. 3 is a block diagram of the MBIST scheme for a Wake Up CAM array. The Execution Unit 310 contains a Scheduler Pipeline Control (SCPCT) 312, a Mapper (MAP) 314, a Scheduler Queue Freelist (SCFRE) 316, and a Picker (SCPIC) 318. The SCPIC 318 contains a wake up array 320 comprising a Destination (Dest) RAM 322 and a plurality of Source (Src) CAMs 324. The source CAMs 324 each include a plurality of entries. In an example embodiment, the number of entries corresponds to the number of queue positions in the freelist 316.

In normal operation, the freelist 316 tracks open scheduler queue positions. When a scheduler queue position is free, the freelist 316 signals the picker 318 through data line 346 that it can pick an instruction to be placed in that queue position. The mapper 314 then writes destination and source data, through data line 344, into the destination RAM 322 and source CAMs 324 associated with that queue position.

For a single-cycle operation, data is written by the mapper 314 in the form of result tags in the destination RAM 322 designating the destination address for the result of an instruction and in the form of source tags in the source CAMs 324 designating the source address(es) for data required for the execution of an instruction. The destination RAM 322 is connected to the source CAMs 324 through a destination RAM broadcast output 348, which allows the destination RAM 322 to “broadcast” a result tag into the source CAMs 324 to “wake up” any instruction waiting to use that result as a source for a queued instruction. The destination RAM broadcast output 348 is configured to send the result tag to all entries in the source CAMs 324. The source CAMs 324 perform a comparison between the result tag that was broadcast and the source tag stored in each CAM cell to generate a match signal that is used in later stages of instruction processing.

When a multi-cycle instruction is released, data is written as tags in the same method described above. Because multi-cycle instructions take longer than one cycle to execute, such instructions are not tracked by the picker 318 and the wake up array 320. Multi-cycle instructions are tracked by operation latency counter logic located in the pipeline control 312. The result tag is broadcast by the pipeline control 312 after a predetermined latency through an alternate tag broadcast line 342. The alternate tag broadcast line 342 connects with the destination RAM broadcast output 348 to allow the result tags from multi-cycle instructions to be broadcast to all entries in the source CAMs 324. The source CAMs 324 perform a comparison between the result tag and the source tags using the same method as described above.

A MBIST engine 311 is connected to the execution unit 310 through a plurality of data lines 340. The data lines 340 are connected to the wake up array 320 through a plurality of multiplexers, such as multiplexers 330a-c. Multiplexer 330a is located inside the pipeline control 312. Multiplexer 330b multiplexes with the data line 344 from the mapper 314 and multiplexer 330c multiplexes with the data line 346 from the freelist 316. Using the multiplexers 330a-c, the MBIST engine 311 can directly interface with the data lines used during normal operation of the execution unit 310.

At initial power-up, the MBIST engine 311 runs a self-test of the wake up array 320 by issuing a signal which enables MBIST operation and disables normal operation of the wake up array 320 in execution unit 310. Disabling normal operation ensures that only the MBIST engine 311 is controlling the wake up array 320. The MBIST engine 311 sends a write address through the freelist multiplexer 330c. Known data is written into the destination RAM 322 and the source CAMs 324 through the mapper multiplexer 330b using the write address.

To test the destination RAM 322, the MBIST engine 311 sends a read address to the picker 318 which is decoded and processed to read out the data stored at that address in the destination RAM 322. The picker 318 then sends the data stored in the destination RAM 322 out to the MBIST engine 311 for comparison with the known data previously written into the destination RAM 322. If the data matches, the destination RAM 322 is working properly.

To test the source CAMs 324, the MBIST engine 311 sends known test comparison data to the pipeline control multiplexer 330a which broadcasts the match data to the source CAMs 324 for comparison using the alternate tag broadcast line 342 and the destination RAM broadcast output 348. The source CAMs 324 perform a comparison operation to generate match/mismatch signals.

In an example embodiment shown in FIG. 3, there may be multiple source CAMs 324. For example, each source CAM 324 may be capable of storing one source tag for each of 40 queue entries. There may be four source CAMs 324 in the wake up array 320, resulting in a total of 160 match/mismatch signals. As a result, it is not feasible to directly observe the match/mismatch signals from all entries of all the source CAMs 324. To allow feasible testing, the MBIST engine 311 also sends multiplexer select signals to a source CAM multiplexer 328. The select signals select the match/mismatch signals from one source CAM through the source CAM multiplexer 328. The signals are encoded and sent to the MBIST engine 311 for comparison to the known data to determine correct operation of that source CAM. By changing the multiplexer select signals sent to the source CAM multiplexer 328, the MBIST engine 311 can test all source CAMs sequentially. In an example embodiment, there are 40 potential match line outputs from each source CAM array with one output indicating a match.

A second way of testing the CAM cells would be to write known test data into the destination RAM 322 and source CAMs 324, broadcasting the source tags into the source CAMs 324 by using the destination RAM broadcast output 348 used during single cycle operation as described above, and analyzing the match output to determine if the CAM functioned properly. By adding additional inputs into the destination RAM broadcast line, the MBIST engine 311 is able to broadcast directly into the CAMs via the alternate tag broadcast line 342. This allows independent testing of the source CAMs 324 without depending on proper operation of the destination RAM. This test requires one extra pull down from the global read bit line which is already present for normal operation and adds minimal additional hardware to support MBIST functionality. The additional hardware needed for this example embodiment is added to the pipeline control 312 to allow the MBIST engine 311 to interface with the alternate tag broadcast line 342. In addition, the source CAM multiplexer 328 is added to the source CAM array 324 to allow for match/mismatch signal selection.

One skilled in the art will notice that the disclosed MBIST scheme will work equally well using traditional CAMs having no dedicated read ports and using external data for comparisons, instead of data broadcast internally by the destination RAM broadcast output 348.

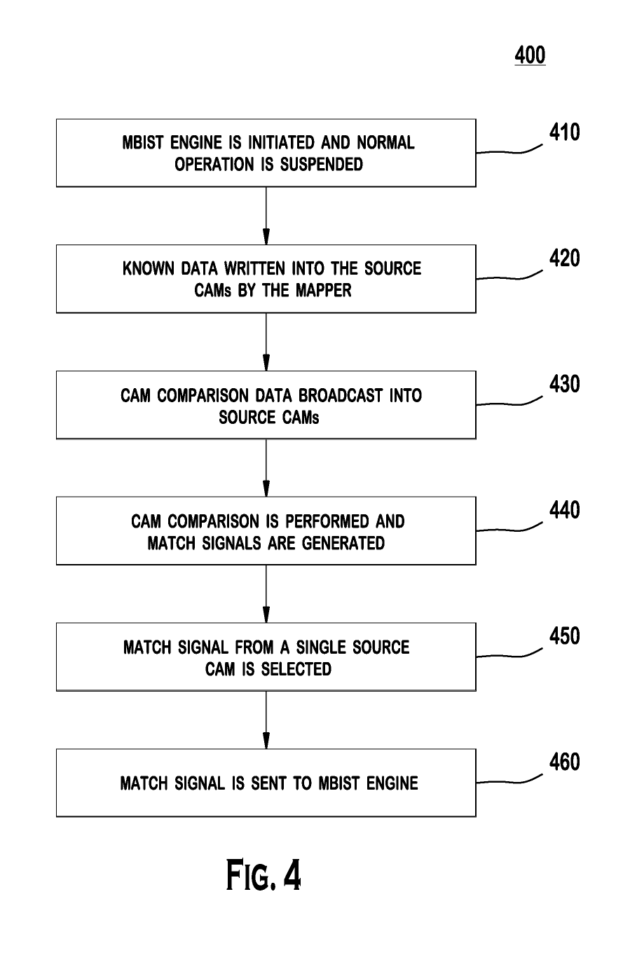

FIG. 4 is a flow chart of a method 400 of testing the source CAMs. The MBIST engine is initialized and normal operation of the wake-up array is suspended (step 410). Known test data is written into the source CAMs (step 420). The MBIST engine broadcasts comparison data into the source CAMs (step 430). The source CAMs perform a comparison between the broadcast comparison data and the data previously written to the source CAMs to generate match signals that indicate whether the broadcast comparison data matches the data stored in the CAM cells (step 440). The MBIST engine selects the match signal from one of the source CAMs (step 450). The selected match signal is sent to the MBIST engine (step 460). If the selected match signals are the same as expected, the CAMs are functioning properly.

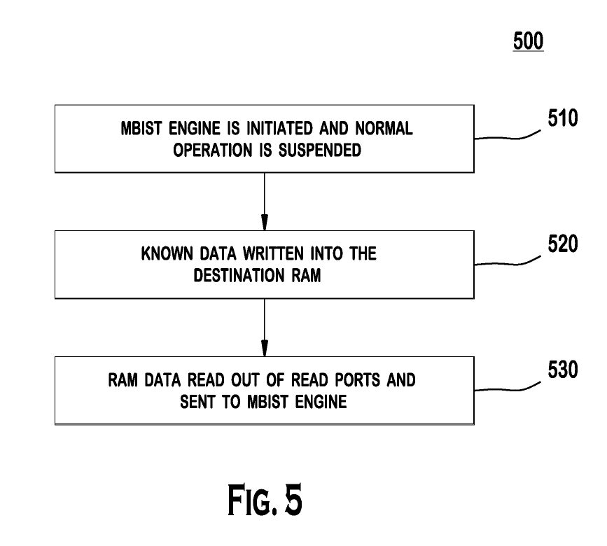

FIG. 5 is a flow chart of a method 500 of testing the destination RAM. The MBIST engine is initialized and normal operation of the wake-up array is suspended (step 510). Known data is written into the destination RAM (step 520). The data is then read out of the destination RAM through dedicated read ports already present and sent to the MBIST engine to determine if the memory elements in the destination RAM are functioning properly (step 530). One skilled in the art will appreciate that the tests of the destination RAM and the source CAMs may be conducted independently of each other or in any order.

Although features and elements are described above in particular combinations, each feature or element may be used alone without the other features and elements or in various combinations with or without other features and elements. The methods or flow charts provided herein may be implemented in a computer program, software, or firmware incorporated in a computer-readable storage medium for execution by a general purpose computer or a processor. Examples of computer-readable storage mediums include a read only memory (ROM), a random access memory (RAM), a register, cache memory, semiconductor memory devices, magnetic media such as internal hard disks and removable disks, magneto-optical media, and optical media such as CD-ROM disks, and digital versatile disks (DVDs).

Suitable processors include, by way of example, a general purpose processor, a special purpose processor, a conventional processor, a digital signal processor (DSP), a plurality of microprocessors, a graphics processing unit (GPU), a DSP core, a controller, a microcontroller, application specific integrated circuits (ASICs), field programmable gate arrays (FPGAs), any other type of integrated circuit (IC), and/or a state machine, or combinations thereof.

Typically, a processor receives instructions and data from a read-only memory (ROM), a random access memory (RAM), and/or a storage device. Storage devices suitable for embodying computer program instructions and data include all forms of non-volatile memory, including by way of example, semiconductor memory devices, magnetic media such as internal hard disks and removable disks, magneto-optical media, and optical media such as CD-ROM disks and DVDs. In addition, while the illustrative embodiments may be implemented in computer software, the functions within the illustrative embodiments may alternatively be embodied in part or in whole using hardware components such as ASICs, FPGAs, or other hardware, or in some combination of hardware components and software components.

Embodiments of the invention may be represented as instructions and data stored on a computer readable storage medium. For example, aspects of the invention may be included in a hardware description language (HDL) code stored on the computer-readable storage medium. When processed, such instructions may generate other intermediary data (e.g., netlists, GDS data, or the like) that may be used to perform a manufacturing process implemented in a semiconductor fabrication facility. The manufacturing process may be adapted to manufacture semiconductor devices (e.g., processors) that embody various aspects of the invention.

While specific embodiments of the present invention have been shown and described, many modifications and variations could be made by one skilled in the art without departing from the scope of the invention. The above description serves to illustrate and not limit the particular invention in any way.

What is claimed is:

1. A method of testing a content addressable memory (CAM) array comprising:
writing known data to the CAM array;
providing comparison data to the CAM array; and
determining whether the CAM array is operating correctly responsive to a comparison of the known data and the comparison data.

2. The method according to claim 1, further comprising:
enabling a test mode to disable normal operation of the CAM array, whereby the CAM array may be tested.

3. The method according to claim 2, wherein the enabling includes sending a signal to the CAM array.

4. The method according to claim 3, wherein the enabling is performed by a test engine.

5. The method according to claim 1, wherein the writing, providing, and determining are performed by a test engine.

6. The method according to claim 1, wherein the CAM array is one of a plurality of CAM arrays, the method further comprising:
selecting one of the plurality of CAM arrays for testing, whereby the determining is performed for each of the plurality of CAM arrays.

7. The method according to claim 6 further comprising:
selecting one of the plurality of CAM arrays, wherein the selecting includes sending a selection signal from a test engine to the plurality of CAM arrays, the selection signal identifying the CAM array to be evaluated.

8. The method according to claim 1, wherein the CAM array is coupled with a random access memory (RAM) array such that an output of the RAM array is provided to the CAM array as the comparison data.

9. The method according to claim 8, wherein the comparison data is provided through an alternate broadcast line connected to the RAM array.

10. An apparatus for testing a content addressable memory (CAM) array, comprising:
a test engine configured to:
write known data to the CAM array; and
provide comparison data to the CAM array;
the CAM array is configured to perform a comparison between the known data and the comparison data; and
the test engine is further configured to determine whether the CAM array is operating correctly responsive to the comparison.

11. The apparatus according to claim 10, wherein the test engine is further configured to send a signal to the CAM array to enable a test mode, wherein enabling the test mode disables normal operation of the CAM array, whereby the CAM array may be tested.

12. The apparatus according to claim 10, wherein the CAM array is one of a plurality of CAM arrays, the apparatus further comprising:
a multiplexer in communication with an output of each of the plurality of CAM arrays; and
the test engine is further configured to send a selection signal to the multiplexer to select an output of one of the plurality of CAM arrays.

13. The apparatus according to claim 10 further comprising:
a random access memory (RAM) array coupled with the CAM array such that an output of the RAM array is provided to the CAM array as the comparison data.

14. The apparatus according to claim 13, wherein the comparison data is provided through an alternate broadcast line connected to the RAM broadcast array.

15. A computer-readable storage medium storing a hardware design code representing an integrated circuit device configured to test a content addressable memory (CAM) array, the hardware design code comprising:
a writing code segment for writing known data to the CAM array;
a providing code segment for providing comparison data to the CAM array; and
a determining code segment for determining whether the CAM array is operating correctly responsive to a comparison of the known data and the comparison data.

16. The computer-readable storage medium of claim 15, wherein the hardware design code is written in a hardware description language (HDL).
